(19) United States
(12) Patent Application Publication
(10) Pub. No.: US 2025/0298930 A1
(43) Pub. Date: Sep. 25, 2025

(54) MODULAR, EXTENSIBLE, INTEROPERABLE AUTONOMY SYSTEMS AND METHODS

(71) Applicant: General Dynamics Mission Systems, Inc., Fairfax, VA (US)

(72) Inventors: Anthony J. Bloch, Savage, MN (US); Benjamin Strasser, Minneapolis, MN (US); Mark Janney, Tempe, AZ (US); Jaraldin Guerrero, West Greenwich, RI (US); Alexandra M. Gitto, Quincy, MA (US); Thomas R. Williams, Phoenix, AZ (US); Gregory R. Osborn, Malverne, NY (US); Patrick V. Haggerty, St. Louis Park, MN (US); Giabo S. Sanchies, Fall River, MA (US); Matt Menard, Taunton, MA (US)

(73) Assignee: General Dynamics Mission Systems, Inc., Fairfax, VA (US)

(21) Appl. No.: 18/612,565

(22) Filed: Mar. 21, 2024

(51) Int. Cl. G06F 30/15

(52) U.S. Cl. CPC G06F 30/15

(57) ABSTRACT

The subject matter described herein discloses apparatus, systems, techniques, and articles for an MEIA (Modular, Extensible, Interoperable Autonomy) architecture that enables a vehicle or autonomous agent with minimal human guidance to perform solo and collaborative missions with other vehicles. The MEIA architecture includes four layers—Awareness, Strategy, Tactics, and Execution. The Execution Layer bookends a single loop through the layers by observing and acting. The Awareness Layer orients, and the Strategy Layer and Tactics Layer split the responsibility of deciding.

### TECHNICAL FIELD

The present disclosure relates generally to autonomous operation in vehicles, and more particularly to autonomous agents and methods in a vehicle for determining vehicle actions for completing a mission.

### BACKGROUND

Automation involves carrying out of some task or series of tasks without human assistance or operation. Autonomy involves the carrying out of some task or series of tasks without human assistance or operation in the face of obstacles or challenges that require adaptation to achieve completion of said task. Autonomy “can learn and adjust to dynamic environments and evolve as the environment around it changes,” while automation focuses narrowly “on a specific task based on well-defined criteria and is restricted to certain tasks it can perform.” Artificial intelligence (AI) involves developing computer programs to complete tasks that would otherwise require human intelligence for completion. These include types of tasks that do not always have a single correct answer for a given input. Autonomous vehicle operation could benefit from improvements in autonomy and AI.

### BRIEF SUMMARY

This summary is provided to describe select concepts in a simplified form that are further described in the Detailed Description. This summary is not intended to identify key or essential features of the claimed subject matter, nor is it intended to be used as an aid in determining the scope of the claimed subject matter.

In some aspects, the techniques described herein relate to a vehicle including: a communication system configured to receive communication data from an entity external to the vehicle regarding mission objectives or commander intent; one or more vehicle actuators; one or more vehicle sensors configured to provide state information regarding the vehicle; and an autonomous agent for directing vehicle behavior. The autonomous agent includes a controller organized with an Awareness Layer, a Strategy Layer, a Tactics Layer, and an Execution Layer. The Awareness Layer is configured to: construct a virtual environment that includes one or more virtual actors that are capable of making decisions and predict future states of the virtual environment and the one or more virtual actors. The Strategy Layer is configured to choose an operating scheme including one or more tasks for the vehicle to execute based on the mission objectives or commander intent. The Tactics Layer is configured to: execute one or more behavioral algorithms to identify actions for implementing the operating scheme that are expressed as commands to the Execution layer. The Execution Layer is configured to receive input from the communication system and the one or more vehicle sensors, convert the commands from the Tactics layer to commands for vehicle actuators to cause the actions identified by the Tactics layer to be carried out, and provide the converted commands to the one or more vehicle actuators.

As an example, the Tactics layer may issue a command for the Execution Layer to “go to this location”, specifying a location in latitude and longitude. That “go to point” command is passed to the Execution Layer which processes the “go to point” command before providing a command to the actuators. If the actuators, in this example, are a gas pedal, a brake, and a steering wheel, based on the vehicle's current location, the Execution Layer may determine that the vehicle needs to make a U-turn to get to the target location. The “go to this location” command provided by the Tactics Layer is analyzed and the Execution Layer may send an “activate” command to the brake, a “deactivate” command to the gas pedal, and a “turn left” command to the steering wheel.

In some aspects, the techniques described herein relate to a method in a vehicle, including: providing a controller organized with an Awareness Layer, a Strategy Layer, a Tactics Layer, and an Execution Layer; constructing, via the Awareness Layer, a virtual environment that includes one or more virtual actors that are capable of making decisions and predicting, via the Awareness Layer, future states of the virtual environment and the one or more virtual actors; choosing, via the Strategy Layer, an operating scheme including one or more tasks for the vehicle to execute based on mission objectives or a commander intent; executing one or more behavioral algorithms by the Tactics Layer; identifying actions for implementing the operating scheme based on executing the one or more behavioral algorithms by the Tactics Layer; expressing, by the Tactics Layer, the identified actions as a set of commands to the Execution Layer; receiving, by the Execution Layer, input from a communication system in the vehicle that is configured to receive communication data from an entity external to the vehicle regarding mission objectives or commander intent; receiving, by the Execution Layer, input from one or more vehicle sensors configured to provide state information regarding the vehicle; converting, by the Execution Layer, the commands from the Tactics layer to commands for vehicle actuators to cause the actions identified by the Tactics layer to be carried out; and providing, by the Execution Layer, the converted commands to one or more vehicle actuators.

In some aspects, the techniques described herein relate to a swarm system including: a plurality of vehicles, wherein each of the plurality of vehicles includes an autonomous agent for directing vehicle behavior, the autonomous agent including a controller organized with an Awareness Layer, a Strategy Layer, a Tactics Layer, and an Execution Layer. The Awareness Layer is configured to: construct a virtual environment representative of a real environment that includes one or more virtual actors that represent one or more real entities in the real environment that are capable of making decisions and predict future states of the virtual environment and the one or more virtual actors. The Strategy Layer is configured to choose an operating scheme that includes one or more tasks for the vehicle to execute based on mission objectives or commander intent. The Tactics Layer is configured to execute one or more behavioral algorithms to identify actions for implementing the operating scheme and express the actions as a set of commands for to the Execution Layer. The Execution Layer is configured to receive input from a communication in the vehicle system and one or more vehicle sensors, convert the commands from the Tactics Layer to commands for vehicle actuators to cause the actions identified by the Tactics Layer to be carried out, and provide the converted commands to one or more vehicle actuators. The autonomous agent in a vehicle in the swarm system is configured to share one or more of operating scheme, identified actions, virtual environment data, virtual actor data, or raw sensor data with another autonomous agent in a vehicle in the swarm system. The autonomous agent in each vehicle in the swarm system is configured to make decisions using its Strategy Layer and the Tactics Layer independently of decisions made by the autonomous agent in other vehicles in the swarm system.

Furthermore, other desirable features and characteristics of the disclosure will become apparent from the subsequent detailed description and the appended claims, taken in conjunction with the accompanying drawings and the preceding background.

### BRIEF DESCRIPTION OF DRAWINGS

The present disclosure will hereinafter be described in conjunction with the following drawing figures, wherein like numerals denote like elements, and wherein:

FIG. 1 is a block diagram depicting an example airspace network.

FIG. 2 is a block diagram depicting an example autonomous agent for directing vehicle behavior.

FIG. 3 is a block diagram depicting example layers within a MEIA controller of an autonomous agent and providing example building blocks within the layers.

FIG. 4 is a diagram illustrating an example patrol mission for a vehicle to perform in an example environment.

FIG. 5 is a diagram illustrating an example target identification mission for a vehicle to perform in an example environment.

FIG. 6 is a priority map for an example Coverage Control mission that may be performed by a swarm of vehicles in an operational area.

FIG. 7 is a flowchart of an example method for autonomously controlling a vehicle.

### DETAILED DESCRIPTION

The following detailed description is merely exemplary in nature and is not intended to limit the invention or the application and uses of the invention. As used herein, the word “exemplary” means “serving as an example, instance, or illustration.” Thus, any embodiment described herein as “exemplary” is not necessarily to be construed as preferred or advantageous over other embodiments. All of the embodiments described herein are exemplary embodiments provided to enable persons skilled in the art to make or use the invention and not to limit the scope of the invention which is defined by the claims. Furthermore, there is no intention to be bound by any expressed or implied theory presented in the preceding technical field, background, brief summary, or the following detailed description.

The subject matter described herein discloses apparatus, systems, techniques, and articles for an MEIA (Modular, Extensible, Interoperable Autonomy) architecture and autonomy framework that enables algorithms for interacting with an unmanned vehicle (UxV) or autonomous agent with minimal human guidance to perform solo and collaborative missions with other UxVs and manned vehicles. The MEIA architecture centers around four layers—Awareness, Strategy, Tactics, and Execution. In various embodiments, the four layers collectively cycle MEIA through an observe-orient-decide-act (OODA) loop. The Execution Layer bookends a single loop by observing and acting. The Awareness Layer orients, and the Strategy Layer and Tactics Layer split the responsibility of deciding. The MEIA architecture is portable, modular, extensible, re-usable, interoperable, and open.

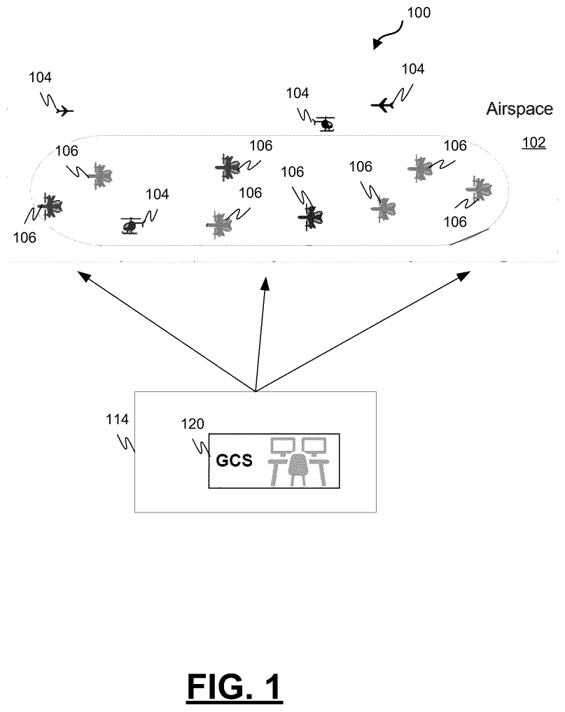

FIG. 1 is a block diagram depicting an example airspace network 100. The example airspace network 100 includes an airspace 102 that includes a plurality of aerial vehicles. The plurality of aerial vehicles in the example airspace 102 includes a plurality of manned aerial vehicles (MAVs) 104 and a plurality of unmanned aerial vehicles (UAVs) 106.

The example airspace network 100 further includes one or more ground control station centers 114. A ground control station center 114 includes one or more ground control stations 120 for one or more ground control station operators. In the example airspace network 100, a ground operator monitors multiple ongoing missions (e.g., delivery, cargo, air taxi, search and rescue, etc.) of autonomous or semi-autonomous vehicles (e.g., MAVs such as an eVTOL (electric Vertical Take-off and Landing vehicle) and a VTOL (Vertical Take-off and Landing vehicle), and UAVs such as drones, and others) from the ground and makes mission-specific decisions. The ground operator uses a ground control station (GCS) 120 in the performance of its duties.

An example GCS 120 includes a set of tools, including hardware, software, and a human-machine interface, to support a ground operator. The GCS 120 forms a relational network with the plurality of MAVs 104 and the plurality of UAVs 106. As used herein the term “relational network” refers to any network in which the various constituents of the network work together to accomplish a purpose.

One or more of the MAVs 104 and/or UAVs 106 are equipped with a communication system configured to receive communications from an entity external to the vehicle (e.g., GCS 120) regarding mission objectives or commander intent, one or more vehicle actuators (e.g., steering, propeller control), one or more vehicle sensors (e.g., camera, GPS) configured to provide state information regarding the vehicle, and an autonomous agent for directing host vehicle behavior. The autonomous agent is configured to autonomously direct its host MAV 104 or UAV 106 to perform solo and/or collaborative missions with other MAVs or UAVs.

In the preceding example, the autonomous agent was resident in a host MAV or a host UAV. In other examples, an autonomous agent may be resident in a vehicle other than a MAV or UAV, such as a land vehicle (e.g., car, truck, military vehicle), watercraft (e.g., civilian or military surface or underwater watercraft), space vehicle (e.g., military or civilian spacecraft, such as a satellite, Flyby spacecraft, Orbiter spacecraft, Atmospheric spacecraft, Lander spacecraft, Penetrator spacecraft, Rover spacecraft, Observatory spacecraft, or Communications & Navigation spacecraft), or other vehicle.

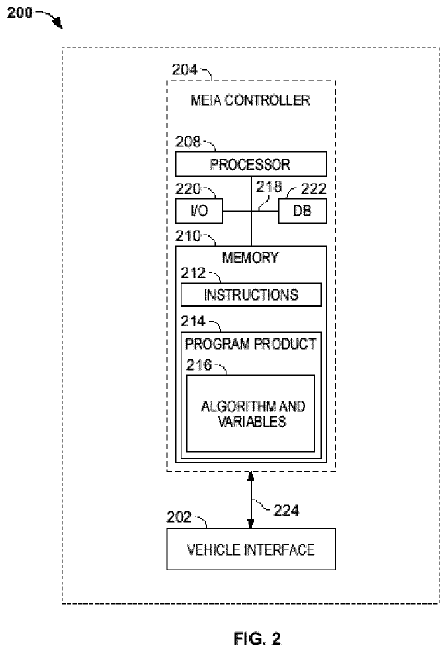

FIG. 2 is a block diagram depicting an example autonomous agent 200 for directing vehicle behavior. The example autonomous agent 200 includes a vehicle interface 202 and an MEIA controller 204. The vehicle interface 202 is configured to communicate with vehicle systems, such as a communication system, vehicle sensors, vehicle actuators, and others.

The example MEIA controller 204 includes a processing component comprising at least one processor 208 and a computer-readable storage device or media (such as memory 210) encoded with programming instructions for configuring the processing component. The processor 208 may comprise any type of processor or multiple processors, any custom-made or commercially available processor, a central processing unit (CPU), a graphics processing unit (GPU), an application specific integrated circuit (ASIC), a field programmable gate array (FPGA), an auxiliary processor among several processors associated with the processing component, a semiconductor-based microprocessor (in the form of a microchip or chip set), any combination thereof, or generally any device for executing instructions to carry out the described operations, tasks, and functions by manipulating electrical signals representing data bits at memory locations in system memory, as well as other processing of signals.

The computer readable storage device or media (e.g., memory 210) may include volatile and nonvolatile storage in read-only memory (ROM), random-access memory (RAM), and keep-alive memory (KAM), for example. KAM is a persistent or non-volatile memory that may be used to store various operating variables while the processor is powered down. The computer-readable storage device or media may be implemented using any of a number of known memory devices such as PROMs (programmable read-only memory), EPROMs (electrically PROM), EEPROMs (electrically erasable PROM), flash memory, or any other electric, magnetic, optical, or combination memory devices capable of storing data, some of which represent executable programming instructions, used by the processing component. The memory 210 may be located on and/or co-located on the same computer chip as the processor 208. Generally, the memory 210 maintains data bits and may be utilized by the processor 208 as storage and/or a scratch pad during operation. Specifically, the memory 210 stores instructions and applications 212. Information in the memory 210 may be organized and/or imported from an external source during an initialization step of a process; it may also be programmed via a user input device. During operation, the processor 208 loads and executes one or more programs, algorithms and rules embodied as instructions and applications 212 contained within the memory 210 and, as such, controls the general operation of the MEIA controller 204.

The memory 210 includes a novel program 216 that includes rules and instructions that, when executed, convert the processing component (e.g., processor 208/memory 210) configuration into the MEIA controller 204, which is a novel MEIA controller that performs the functions, techniques, and processing tasks associated with autonomously directing vehicle behavior. The novel program 216 directs the processing component to provide a controller organized with an Awareness Layer, a Strategy Layer, a Tactics Layer, and an Execution Layer, and configured to use the Awareness Layer, the Strategy Layer, the Tactics Layer, and the Execution Layer to direct vehicle behavior. In various embodiments, the controller is configured to cycle through observing, orienting, deciding, and acting using the Awareness Layer, the Strategy Layer, the Tactics Layer, and the Execution Layer to direct vehicle behavior. The novel program 216 and associated stored variables may be stored in a functional form on computer readable media, for example, as depicted, in memory 210. While the depicted exemplary embodiment of the MEIA controller is described in the context of a fully functioning computer system, those skilled in the art will recognize that the mechanisms of the present disclosure are capable of being distributed as a program product 214.

As a program product 214, one or more types of non-transitory computer-readable signal bearing media may be used to store and distribute the program 216, such as a non-transitory computer readable medium bearing the program 216 and containing therein additional computer instructions for causing a computer processor (such as the processor 208) to load and execute the program 216. Such a program product 214 may take a variety of forms, and the present disclosure applies equally regardless of the type of computer-readable signal bearing media used to carry out the distribution. Examples of signal bearing media include recordable media such as floppy disks, hard drives, memory cards and optical disks, and transmission media such as digital and analog communication links. It will be appreciated that cloud-based storage and/or other techniques may also be utilized as memory 210 in certain embodiments.

In various embodiments, the processing component (e.g., processor 208/memory 210) configuration of the MEIA controller 204 may be communicatively coupled (via a bus 218) to an input/output (I/O) interface 220, and a database 222. The bus 218 serves to transmit programs, data, status and other information or signals between the various components of the MEIA controller 204. The bus 218 can be any suitable physical or logical means of connecting computer systems and components. This includes, but is not limited to, direct hard-wired connections, fiber optics, infrared and wireless bus technologies.

The I/O interface 220 enables intra MEIA controller communication, as well as communications between the MEIA controller 204 and other system components, and between the MEIA controller 204 and the external data sources via the communication system and fabric 224. The I/O interface 220 may include one or more network interfaces and can be implemented using any suitable method and apparatus. In various embodiments, the I/O interface 220 is configured to support communication from an external system driver and/or another computer system. In one embodiment, the I/O interface 220 is integrated with the communication system and fabric 224 and obtains data from external data source(s) directly. Also, in various embodiments, the I/O interface 220 may support communication with technicians, and/or one or more storage interfaces for direct connection to storage apparatuses, such as the database 222. In some embodiments, the database 222 is part of the memory 210. In various embodiments, the database 222 is integrated, either within the MEIA controller 204 or external to it.

The example MEIA controller 204 is configured by the novel program 216 with an Awareness Layer, a Strategy Layer, a Tactics Layer, and an Execution Layer. The example MEIA controller 204 is configured by the novel program 216 to use the Awareness Layer, the Strategy Layer, the Tactics Layer, and the Execution Layer to direct vehicle behavior. In various embodiments, the example MEIA controller 204 is configured by the novel program 216 to cycle through observing, orienting, deciding, and acting using the Awareness Layer, the Strategy Layer, the Tactics Layer, and the Execution Layer to direct vehicle behavior.

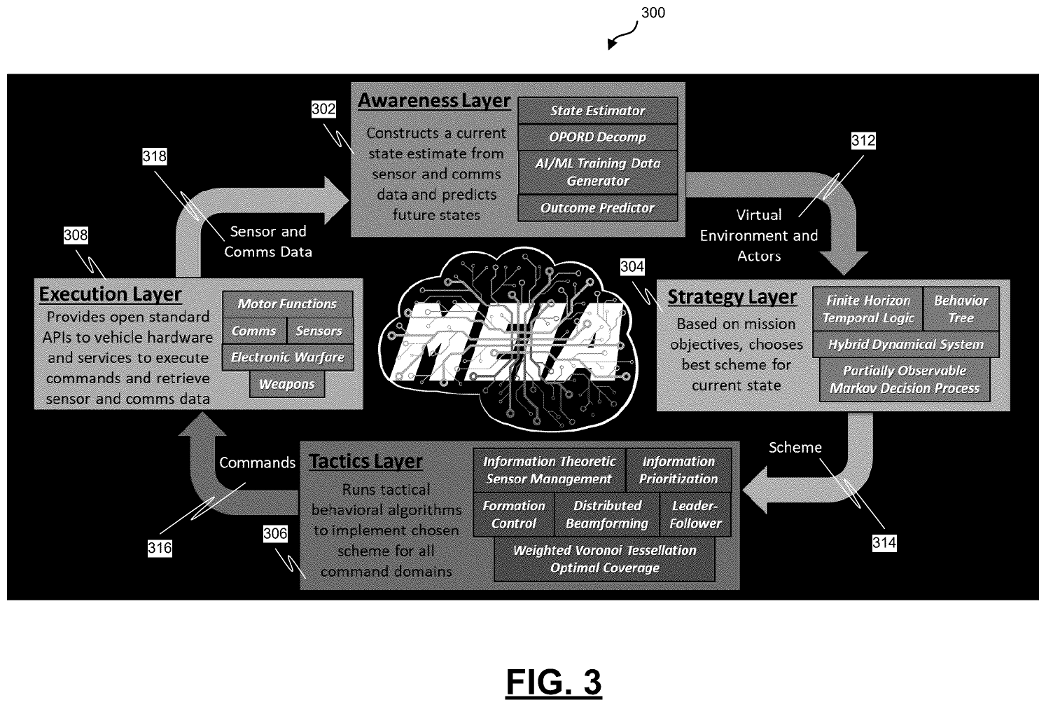

FIG. 3 is a block diagram depicting example layers within a MEIA controller 300 (e.g., MEIA controller 204) of an autonomous agent and providing example building blocks within the layers. The MEIA architecture centers around four layers-Awareness Layer 302, Strategy Layer 304, Tactics Layer 306, and Execution Layer 308. In various embodiments, the four layers collectively cycle the MEIA controller 300 through an observe-orient-decide-act (OODA) loop. The Execution Layer 308 bookends a single loop by observing and acting. The Awareness Layer 302 orients, and the Strategy Layer 304 and Tactics Layer 306 split the responsibility of deciding. Also, the Awareness Layer 302 connects to the other layers (304, 306, 308) as needed for referencing the virtual environment and actors.

The Awareness Layer 302 orients by curating the data that serves as input to the other layers and drives their decision-making processes. The Awareness Layer 302 constructs a virtual environment and virtual actors 312 (defined as any entities in the environment capable of making decisions) that live in that environment by transforming raw sensor and communication data ingested by the MEIA controller 300 into a state estimate of the environment and its actors. Algorithms relating to sensor or track fusion and updating tracks for virtual actors 312 are included in the Awareness Layer 302. Other example algorithms included with the Awareness Layer 302 may include a state estimator, an operation order decomposition (OPORD Decomp) algorithm, an artificial intelligence/machine learning (AI/ML) training data generator, and an outcome predictor algorithm.

As needed, the Awareness Layer 302 predicts future states based on the current environmental state and likely courses of action of the virtual actors 312. In this way, the Awareness Layer 302 updates the data it curates even when operating with partial information in contested environments. Some candidate algorithms or models for the Awareness Layer 302 for making predictions are the joint multitarget probability density tracking algorithm and the online deep learning model for behavior prediction.

Additionally, the example Awareness Layer 302 accommodates machine learning (ML) by hosting those algorithms that generate rewards to drive the training of ML algorithms throughout the MEIA controller 300. In some systems, ML is driven by rewards generated by the simulation environment; however, the MEIA controller 300 incorporates rewards directly in the Awareness Layer 302 to allow for ML training both in the simulated environment and in real-world operations. For example, when training an ML model for an intelligence, surveillance, reconnaissance (ISR) mission, the Awareness Layer 302 may give rewards based on the number of targets spotted, something that can be calculated by the Awareness Layer 302 both in a simulated environment and in the real world. This allows ML training to not be limited to simulated environments only. Lastly, the Awareness Layer 302 serves as the gateway between a human operator and the other layers of the MEIA controller 300, parsing communications and providing data to the other layers, which can see those inputs and instructions and follow them accordingly. For example, when a human operator (e.g., a ground operator at a GCS 120) sends a mission to an autonomous agent, the Awareness Layer 302 stores the mission information inside the virtual actor representing itself. The Strategy Layer 304 extracts the mission data from the virtual actor it receives from the Awareness Layer 302 and decides the current scheme that the Tactics Layer 306 executes.

In various embodiments, the autonomous agent can receive a mission from a human operator and perform functions to implement the mission without human control at the various layers. In some embodiments, human control is provided at a variety of levels across the layers. Different specific implementations of the MEIA controller 300 may allow a human to send a given scheme or some instructions for basic maneuver actions instead of a mission. In these implementations, the Awareness Layer 302 would update the virtual actor representing the autonomous agent to include the instructions the human sent it, and then the Tactics Layer 306 and the Execution Layer 308 would extract those instructions and follow them instead of the scheme or commands they would receive from the Strategy Layer 304 or the Tactics Layer 306, respectively. In various embodiments, the MEIA controller 300 is configured to autonomously make only a subset of the actions required for operation while it depends on the human to decide the rest of the actions not covered by that specific MEIA solution.

The Strategy Layer 304 references knowledge of mission objectives and operator's or commander's intent to choose the best scheme 314 across the mission timelines; the scheme 314 includes which tactics algorithms or tasks it will run and the appropriate parameters to drive those algorithms. The Strategy Layer 304 can change its scheme 314 at any moment based on the state of the mission in context of the dynamic virtual environment and virtual actors 312. The Strategy Layer 304 accommodates a variety of algorithms ranging from scripted strategy decision-making to ML decision-making to finite-horizon temporal logic algorithms as options for the MEIA controller 300 to navigate the strategy space. The Strategy Layer 304 can report key performance metrics used for decision-making by humans in/on the loop and for post-mission analysis. In some embodiments, human operators may make some strategy-level decisions for the Strategy Layer 304. In other embodiments, the Strategy Layer 304 makes all of the strategy-level decisions for the MEIA controller 300 using available technology and algorithms.

The Tactics Layer 306 leverages the virtual environment and virtual actors 312 to execute behavioral algorithms or tasks needed to implement the requested scheme 314. Tactical decision-making is at a lower level than strategic decision-making, and it encompasses all action domains available to the agent (e.g., maneuver, sensor management, weapons management, comms transmissions, jamming, spoofing, etc.). The Strategy Layer 304 decides what task or tasks (collectively called a scheme) ought to be executed and when to transition to the next task(s), while the Tactics Layer 306 decides what actions are needed to execute the set of tasks currently selected by the Strategy Layer 304. The result of Tactics decision-making is a set of commands 316 that the Tactics Layer 306 sends to the Execution Layer 308 to carry out. This may be done through a single algorithm that guides actions across all domains or through a combination of algorithms that each guide a subset of all the action domains. The Tactics Layer 306 may include a variety of algorithms and models including an Information Theoretic Sensor Management algorithm for guiding the movements of sensor fields of view within a swarm of UxVs (unmanned vehicles) to search an area and track targets, weighted Voronoi Tessellation Optimal Coverage algorithm for swarm coverage control, a distributed beam forming algorithm for enhancing the range of comms and sensors for collaborative swarm formations.

The Execution Layer 308 is responsible for acting and realizing the decisions made by the Tactics Layer 306 and for observing and feeding the Awareness Layer 302 the information it needs, such as sensor readings and data received over communications. The autonomy algorithms involved at this layer may include auto-pilot for navigating to a target waypoint, comms management for mesh networking, etc. The Execution Layer 308 may also include autonomy that provides guard rails to ensure safe behavior: for example, by guiding an UxV around obstacles in its path on its way to a desired waypoint set by the Tactics Layer 306. Algorithms like safety barrier certificates for collision avoidance in vehicle maneuvers may be included in this layer. The Execution Layer 308 may interoperate with existing vehicle capabilities and tools, such as auto pilot, and ensure the commands 316 provided as output by the Tactics Layer 306 are sent to the appropriate destination for execution.

The Execution Layer 308 can provide open standard APIs to mission system and vehicle command, control, and status services. The use of open standard APIs can standardize the data structures passed across the interfaces between the layers as well as function signatures, to allow new algorithms and models to be added inside each extensible layer for future enhancement opportunities. In various embodiments, the core of each data structure is standardized, but each also includes dynamic fields for various parameters. For example, the core of the data structure passed across the interface from the Strategy Layer 304 to the Tactics Layer 306 is the scheme 314 (i.e., the selected tasks to execute). Depending on the algorithm, the scheme 314 may require parameters. If the task is to search for targets, the parameters may include a specific region of interest and a priority density function across the region to guide the search.

In various embodiments, the Awareness Layer 302 is configured to construct a virtual environment that includes one or more virtual actors 312 that are capable of making decisions (based on sensor and comms data 318), and predict future states of the virtual environment and the one or more virtual actors 312. In various embodiments, the Strategy Layer 304 is configured to choose an operating scheme 314 including one or more tasks for the vehicle to execute. In various embodiments, the Strategy Layer 304 models the strategy space built from the mission objectives or commander intent and provides a framework through which the agent navigates and evaluates strategies (via models and related algorithms such as a finite horizon temporal logic, behavior tree, hybrid dynamical system, partially observable Markov Decision process). In various embodiments, the Tactics Layer 306 is configured to execute one or more behavioral algorithms (e.g., information theoretic sensor management, information prioritization, formation control, distributed beamforming, leader-follower, weighted Voronoi Tessellation Optimal Coverage, etc.) to identify actions for implementing the operating scheme 314, and express the actions as a set of commands 316 for the Execution Layer 308. In various embodiments, the Execution Layer 308 is configured to receive input from the communication system and the one or more vehicle sensors (which is provided as sensor and comms data 318 to the Awareness Layer 302) and provide output to the one or more vehicle actuators based on the commands 316 from the Tactics Layer 306. In various embodiments, the Execution Layer 308 is configured to convert the commands from the Tactics Layer to commands for vehicle actuators to cause the actions identified by the Tactics Layer to be carried out, and provide the converted commands to one or more vehicle actuators. In various embodiments, the Awareness Layer is further configured to parse the sensor and comms data 318 and provide relevant data or instructions from the sensor and comms data 318 to one or more of the Strategy Layer 304, the Tactics Layer 306, and the Execution Layer 308.

In various embodiments, the MEIA controller 300 may be extended, for example, to replace whole layers as needed (e.g., to replace the Strategy Layer 304 and the Tactics Layer 306 with a layer that calculates both strategy and tactics and outputs commands to the Execution Layer 308).

In various embodiments, one version of a layer may be swapped out for a different version of the layer that has been developed for a particular scenario: for example, a Tactics Layer for an unmanned ground vehicle can be swapped with one for an unmanned aerial vehicle.

In another example, with a group of UxVs deployed as a swarm with no leader vehicle, each vehicle will use its Strategy and Tactics Layers to make decisions in a decentralized manner (i.e. independently); however, the MEIA controller on each vehicle in the swarm may still share its plans and the information available to it (e.g. virtual environment data, virtual actor data, raw sensor data, etc.) with each to provide better context as they each make their decisions. The Awareness Layer can be synchronized or distributed across multiple agents. If a vehicle encounters some obstacle or difficulty, the MEIA controller may send communications asking for others in the swarm to help. In turn, if the MEIA controller receives requests for help from other members in the swarm, it will use this information to inform its decisions in the Strategy and Tactics Layers. Sometimes the MEIA controller may decide to help while other times the MEIA controller may decide the mission is more likely to succeed by ignoring the request for help and focusing on their role in the mission. In various embodiments, a request for help may include a request for additional presence in a given area by a teammate to increase the total sensor coverage of that area. The Strategy Layer can perform “role identification” in a larger team context. In various embodiments, this may mean that for an ISR mission the Strategy Layer of one teammate identifies its role to be the “tracker” of the team while it assumes its teammate will be the “searcher”. In such a case, the “trackers” maintain coverage of targets once they are spotted while “searchers” continue to search the area for new targets. Many Tactics Layer behaviors involve collaboration between vehicles. As an example, if several vehicles in the swarm have been identified as “searchers” by their Strategy Layer, they may collaborate in their execution of the “search” task by dividing the larger search area into smaller areas of responsibility. This can be done explicitly through communications between the teammates or implicitly for various embodiments and behavior algorithm implementations. In these ways, the MEIA controller enables multi-agent autonomy across a swarm of autonomous vehicles.

In another example, with a group of UxVs deployed as a swarm with a leader agent, the leader agent could be equipped with a more advanced mission system that includes copies of the Strategy and Tactics Layers of the other agents to calculate schemes and commands and send instructions to teammates after the leader has decided the best course of action. Equipped with layers from its teammates, the leader agent could project the state of the environment forward across the courses of actions it considers for all its teammates to predict likely outcomes.

In another example, in disconnected, intermittent, and limited environments, a single agent may be equipped with multiple versions of the different layers so that, when communications are jammed or intermittent, the agent can anticipate what the other agents in its swarm are doing to effectively reason about outcomes based on the unique Strategy and Tactics Layers which it has for the agent. In this way, the Awareness Layer can project the virtual actors forward in time because it can reason what they would likely do because they can leverage those Strategy and Tactics Layers that that teammate is using to make its decisions.

In various embodiments, the MEIA controller 300 also includes tracing services (not shown) that store relevant information between components and within layers for post-mission performance evaluation and analysis or for providing explanations of MEIA's decisions to the human operator during the mission.

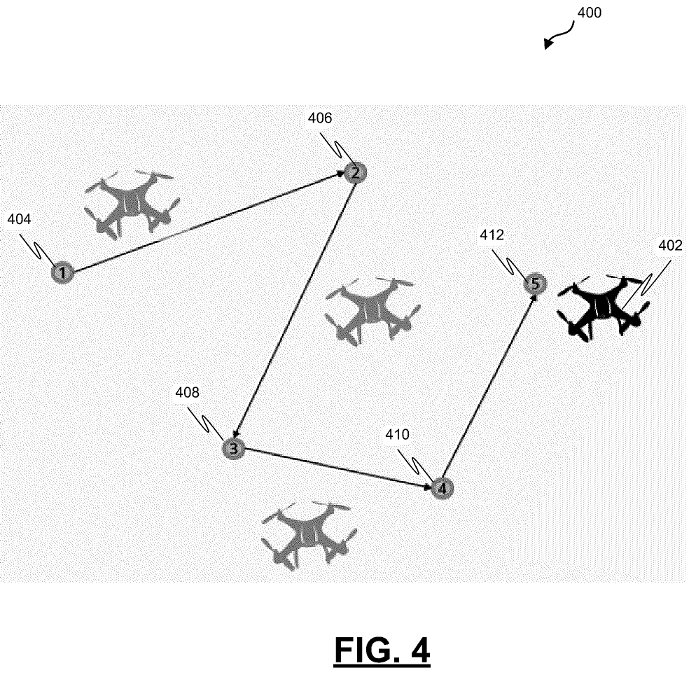

FIG. 4 is a diagram illustrating an example patrol mission for a vehicle 402 to perform in an example operational area 400. In this example, an operator may choose a set of valid waypoints (404, 406, 408, 410, 412) inside the operational area 400 for the vehicle 402 to traverse and communicates the information to the vehicle 402. The Execution Layer 308 of a MEIA controller 300 in the vehicle 402 observes the communication with the set of waypoints, a command to perform a patrol mission, and sensor data regarding the vehicle 402, and feeds the Awareness Layer 302 with the set of waypoints, the command, and the sensor data. The Awareness Layer 302 constructs a virtual environment (e.g., a virtual depiction of the operational area 400 and the waypoints 404, 406, 408, 410, 412) that includes a virtual actor (e.g., a virtual representation of the vehicle 402). The Strategy Layer 304 chooses an operating scheme for traversing the waypoints (e.g., traveling to a waypoint and loitering for three seconds before continuing towards the next waypoint). The Tactics Layer 306 identifies actions for implementing the operating scheme, and determines a set of commands to cause the identified actions to be carried out. The Execution Layer 308 provides output to one or more vehicle actuators based on the commands from the Tactics Layer 306 to cause the vehicle to traverse the waypoints.

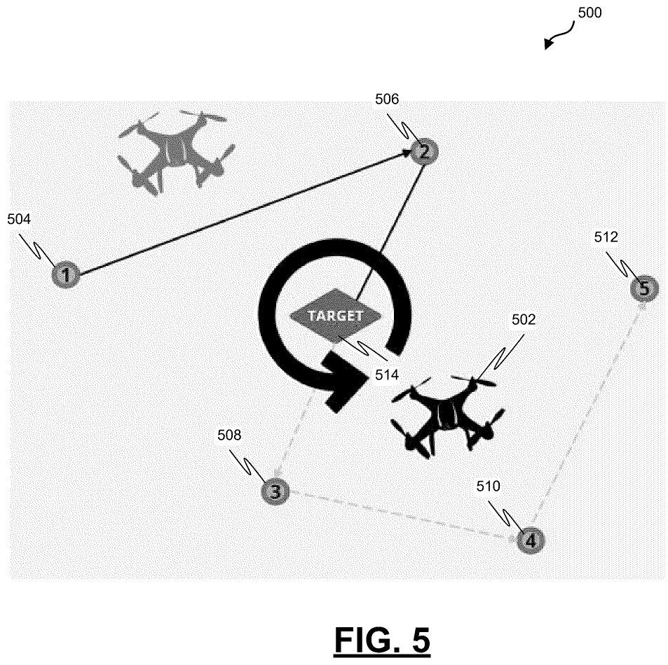

FIG. 5 is a diagram illustrating an example target identification mission for a vehicle 502 to perform in an example operational area 500. In this example, an operator may choose a set of valid waypoints (504, 506, 508, 510, 512) inside the operational area 500 for the vehicle 502 to traverse in an attempt to locate a target 514 and communicate the information to the vehicle 502. The Execution Layer 308 of a MEIA controller 300 in the vehicle 502 observes the communication with the set of waypoints, command to perform a target identification mission, and sensor data regarding the vehicle 502, and feeds the Awareness Layer 302 with the set of waypoints, the command, and the sensor data. The Awareness Layer 302 constructs a virtual environment (e.g., a virtual depiction of the operational area 500 and the waypoints 504, 506, 508, 510, 512) that includes a virtual actor (e.g., a virtual representation of the vehicle 502). The Strategy Layer 304 chooses an operating scheme for traversing the waypoints (e.g., traveling to a waypoint and loitering for three seconds before continuing towards the next waypoint unless the target is found). The Tactics Layer 306 identifies actions for implementing the operating scheme, and determines a set of commands to cause the identified actions to be carried out. The Execution Layer 308 provides output to one or more vehicle actuators based on the commands from the Tactics Layer 306 to cause the vehicle to traverse the waypoints. In this example, the vehicle 502 travels to a waypoint, loiters for 3 seconds while searching for the target, and moves on to the next waypoint if the target is not located. When the vehicle 502 detects that it is within a pre-defined distance of the target 514, the vehicle dynamically changes course by abandoning the remaining waypoints in the path and traveling directly to the target location. Once the vehicle 502 arrives at the target location, it flies in a circle over the target 514 and makes an audible beeping alert until given further instructions by the operator.

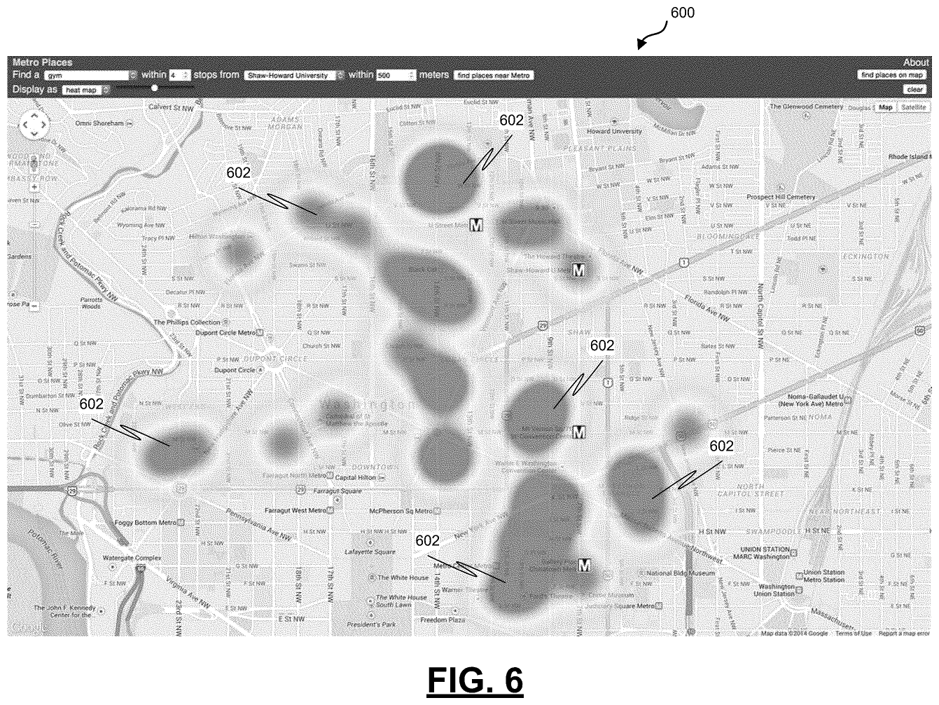

FIG. 6 is a priority map for an example Coverage Control mission that may be performed by a swarm of vehicles in an operational area 600. In this example, the mission is performed by a swarm consisting of three vehicles. An operator sends a priority density function or priority map to each vehicle in real time to express areas of interest 602 within the operational area 600 that require attention and need coverage. In this example, two of the vehicles patrol pre-defined routes while the third vehicle executes a coverage control algorithm to dynamically guide its movement, attempting to optimize coverage of the priority map by dynamically identifying and filling in gaps in the coverage that emerge as the other two vehicles execute their patrols. The Execution Layer 308 of a MEIA controller 300 in the third vehicle observes the communication from the operator, command to perform a coverage control mission, and sensor data regarding the swarm, and feeds the Awareness Layer 302 with this information. The Awareness Layer 302 constructs a virtual environment (e.g., a virtual depiction of the operational area 600 and areas of interest 602) that includes three virtual actors (e.g., virtual representation of the three vehicles in the swarm). The Strategy Layer 304 chooses an operating scheme for patrolling the area of interest. The Tactics Layer 306 identifies actions for implementing the operating scheme, and determines a set of commands to cause the identified actions to be carried out. The Execution Layer 308 provides output to one or more vehicle actuators based on the commands from the Tactics Layer 306 to cause the vehicle to patrol the areas of interest. The third vehicle executes a coverage control algorithm to dynamically guide its movement, attempting to optimize coverage of the priority map by dynamically identifying and filling in gaps in the coverage that emerge as the other vehicles execute their patrols.

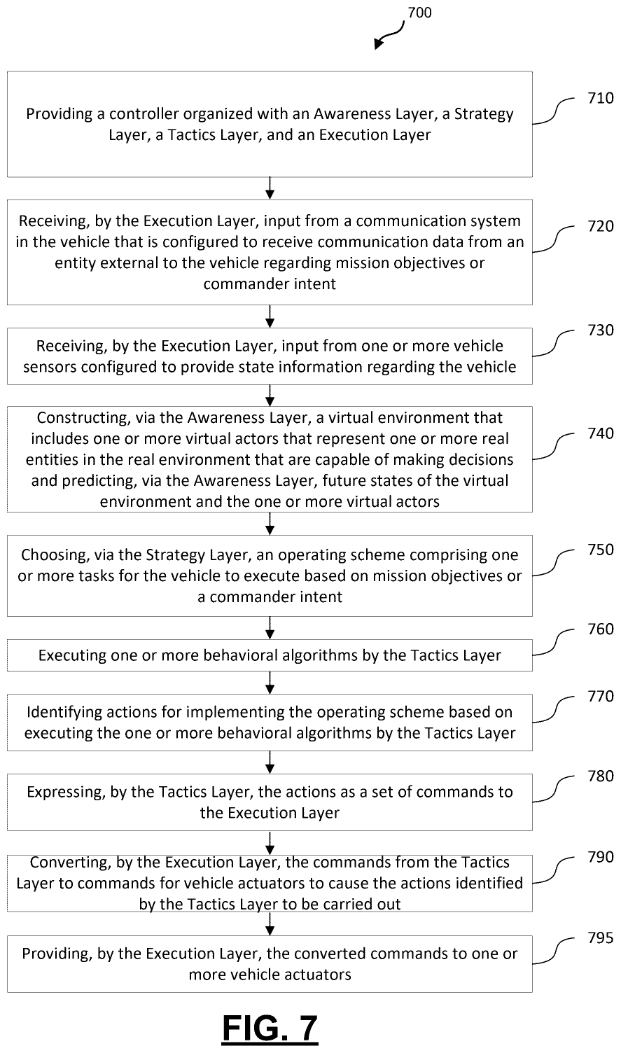

FIG. 7 is a flowchart of an example method 700 for autonomously controlling a vehicle. At step 710, the example method 700 includes providing a controller organized with an Awareness Layer, a Strategy Layer, a Tactics Layer, and an Execution Layer. In various embodiments, the controller is configured to cyclically observe, orient, decide, and act using the Awareness Layer, the Strategy Layer, the Tactics Layer, and the Execution Layer.

At step 720, the example method 700 includes receiving, by the Execution Layer, input from a communication system in the vehicle that is configured to receive communication data from an entity external to the vehicle regarding mission objectives or commander intent.

At step 730, the example method 700 includes receiving, by the Execution Layer, input from one or more vehicle sensors configured to provide state information regarding the vehicle.

At step 740, the example method 700 includes constructing, via the Awareness Layer, a virtual environment that includes one or more virtual actors that represent one or more real entities in the real environment that are capable of making decisions and predicting, via the Awareness Layer, future states of the virtual environment and the one or more virtual actors. In various embodiments, constructing the virtual environment includes transforming raw sensor data from the one or more vehicle sensors and communication data from a communication system into a current state estimate of the virtual environment and the one or more virtual actors. In various embodiments, predicting the future states of the virtual environment and the one or more virtual actors comprises predicting the future states of the virtual environment and the one or more virtual actors based on the current state estimate of the virtual environment and the one or more virtual actors and a likely course of action for the one or more virtual actors. In various embodiments, the method further includes parsing, via the Awareness Layer, the communication data and providing relevant data or instructions from the communication data to one or more of the Strategy Layer, the Tactics Layer, and the Execution Layer.

At step 750, the example method 700 includes choosing, via the Strategy Layer, an operating scheme comprising one or more tasks for the vehicle to execute based on mission objectives or a commander intent. In various embodiments, the method further includes deciding when to transition to a next task via the Strategy Layer.

At step 760, the example method 700 includes executing one or more behavioral algorithms by the Tactics Layer. In various embodiments the one or more behavioral algorithms include an Information Theoretic Sensor Management algorithm for guiding the movements of sensor fields of view within a swarm of vehicles to search an area and track targets, a weighted Voronoi Tessellation Optimal Coverage algorithm for swarm coverage control, a distributed beam forming algorithm for enhancing the range of comms and sensors for collaborative swarm formations, a maneuver algorithm, a sensor management algorithm, a weapons management algorithm, a comms transmission algorithm, a jamming algorithm, a spoofing algorithm, and others.

At step 770, the example method 700 includes identifying actions for implementing the operating scheme based on executing the one or more behavioral algorithms by the Tactics Layer.

At step 780, the example method 700 includes expressing, by the Tactics Layer, the actions as a set of commands to the Execution Layer.

In various embodiments, the Strategy Layer decides what task or tasks (collectively called a scheme) ought to be executed and when to transition to the next task(s), while the Tactics Layer decides what actions are needed to execute the set of tasks currently selected by the Strategy Layer.

At step 790, the example method 700 includes converting, by the Execution Layer, the commands from the Tactics Layer to commands for vehicle actuators to cause the actions identified by the Tactics Layer to be carried out.

At step 795, the example method 700 includes providing, by the Execution Layer, the converted commands to one or more vehicle actuators.

While the foregoing examples have been described with reference to a moving vehicle, such as an aerial vehicle, spacecraft, land vehicle, watercraft, etc., apparatus, systems, techniques, and articles described herein may also apply to fixed-in-place vehicles such as an autonomous watch tower which cannot move but performs other actions like positioning sensors, transmitting communications, launching weapons, etc.

Those of skill in the art will appreciate that the various illustrative logical blocks, modules, circuits, and algorithm steps described in connection with the embodiments disclosed herein may be implemented as electronic hardware, computer software, or combinations of both. Some of the embodiments and implementations are described above in terms of functional and/or logical block components (or modules) and various processing steps. However, it should be appreciated that such block components (or modules) may be realized by any number of hardware, software, and/or firmware components configured to perform the specified functions. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present invention. For example, an embodiment of a system or a component may employ various integrated circuit components, e.g., memory elements, digital signal processing elements, logic elements, look-up tables, or the like, which may carry out a variety of functions under the control of one or more microprocessors or other control devices. In addition, those skilled in the art will appreciate that embodiments described herein are merely exemplary implementations.

The various illustrative logical blocks, modules, and circuits described in connection with the embodiments disclosed herein may be implemented or performed with a general purpose processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general-purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The steps of a method or algorithm described in connection with the embodiments disclosed herein may be embodied directly in hardware, in a software module executed by a processor, or in a combination of the two. A software module may reside in RAM memory, flash memory, ROM memory, EPROM memory, EEPROM memory, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor. The processor and the storage medium may reside in an ASIC.

Techniques and technologies may be described herein in terms of functional and/or logical block components, and with reference to symbolic representations of operations, processing tasks, and functions that may be performed by various computing components or devices. Such operations, tasks, and functions are sometimes referred to as being computer-executed, computerized, software-implemented, or computer-implemented. In practice, one or more processor devices can carry out the described operations, tasks, and functions by manipulating electrical signals representing data bits at memory locations in the system memory, as well as other processing of signals. The memory locations where data bits are maintained are physical locations that have particular electrical, magnetic, optical, or organic properties corresponding to the data bits. It should be appreciated that the various block components shown in the figures may be realized by any number of hardware, software, and/or firmware components configured to perform the specified functions. For example, an embodiment of a system or a component may employ various integrated circuit components, e.g., memory elements, digital signal processing elements, logic elements, look-up tables, or the like, which may carry out a variety of functions under the control of one or more microprocessors or other control devices.

When implemented in software or firmware, various elements of the systems described herein are essentially the code segments or instructions that perform the various tasks. The program or code segments can be stored in a processor-readable medium or transmitted by a computer data signal embodied in a carrier wave over a transmission medium or communication path. The “computer-readable medium”, “processor-readable medium”, or “machine-readable medium” may include any medium that can store or transfer information. Examples of the processor-readable medium include an electronic circuit, a semiconductor memory device, a ROM, a flash memory, an erasable ROM (EROM), a floppy diskette, a CD-ROM, an optical disk, a hard disk, a fiber optic medium, a radio frequency (RF) link, or the like. The computer data signal may include any signal that can propagate over a transmission medium such as electronic network channels, optical fibers, air, electromagnetic paths, or RF links. The code segments may be downloaded via computer networks such as the Internet, an intranet, a LAN, or the like.

Some of the functional units described in this specification have been referred to as “modules” in order to more particularly emphasize their implementation independence. For example, functionality referred to herein as a module may be implemented wholly, or partially, as a hardware circuit comprising custom VLSI circuits or gate arrays, off-the-shelf semiconductors such as logic chips, transistors, or other discrete components. A module may also be implemented in programmable hardware devices such as field programmable gate arrays, programmable array logic, programmable logic devices, or the like. Modules may also be implemented in software for execution by various types of processors. An identified module of executable code may, for instance, comprise one or more physical or logical modules of computer instructions that may, for instance, be organized as an object, procedure, or function. Nevertheless, the executables of an identified module need not be physically located together, but may comprise disparate instructions stored in different locations that, when joined logically together, comprise the module and achieve the stated purpose for the module. Indeed, a module of executable code may be a single instruction, or many instructions, and may even be distributed over several different code segments, among different programs, and across several memory devices. Similarly, operational data may be embodied in any suitable form and organized within any suitable type of data structure. The operational data may be collected as a single data set, or may be distributed over different locations including over different storage devices, and may exist, at least partially, merely as electronic signals on a system or network.

In this document, relational terms such as first and second, and the like may be used solely to distinguish one entity or action from another entity or action without necessarily requiring or implying any actual such relationship or order between such entities or actions. Numerical ordinals such as “first,” “second,” “third,” etc. simply denote different singles of a plurality and do not imply any order or sequence unless specifically defined by the claim language. The sequence of the text in any of the claims does not imply that process steps must be performed in a temporal or logical order according to such sequence unless it is specifically defined by the language of the claim. The process steps may be interchanged in any order without departing from the scope of the invention as long as such an interchange does not contradict the claim language and is not logically nonsensical.

Furthermore, depending on the context, words such as “connect” or “coupled to” used in describing a relationship between different elements do not imply that a direct physical connection must be made between these elements. For example, two elements may be connected to each other physically, electronically, logically, or in any other manner, through one or more additional elements.

As used herein, the term “substantially” denotes within 5% to account for manufacturing tolerances. Also, as used herein, the term “about” denotes within 5% to account for manufacturing tolerances.

While at least one exemplary embodiment has been presented in the foregoing detailed description of the invention, it should be appreciated that a vast number of variations exist. It should also be appreciated that the exemplary embodiment or exemplary embodiments are only examples, and are not intended to limit the scope, applicability, or configuration of the invention in any way. Rather, the foregoing detailed description will provide those skilled in the art with a convenient road map for implementing an exemplary embodiment of the invention. It being understood that various changes may be made in the function and arrangement of elements described in an exemplary embodiment without departing from the scope of the invention as set forth in the appended claims.

What is claimed is:

1. A vehicle comprising:
a communication system configured to receive communication data from an entity external to the vehicle regarding mission objectives or commander intent;
one or more vehicle actuators;
one or more vehicle sensors configured to provide state information regarding the vehicle; and
an autonomous agent for directing vehicle behavior, the autonomous agent comprising a controller organized with an Awareness Layer, a Strategy Layer, a Tactics Layer, and an Execution Layer;
wherein the Awareness Layer is configured to:
construct a virtual environment representative of a real environment that includes one or more virtual actors that represent one or more real entities in the real environment that are capable of making decisions; and
predict future states of the virtual environment and the one or more virtual actors;
wherein the Strategy Layer is configured to choose an operating scheme comprising one or more tasks for the vehicle to execute based on the mission objectives or commander intent;
wherein the Tactics Layer is configured to:
execute one or more behavioral algorithms to identify actions for implementing the operating scheme; and
express the actions as a set of commands to the Execution Layer; and
wherein the Execution Layer is configured to receive input from the communication system and the one or more vehicle sensors, convert the commands from the Tactics Layer to commands for vehicle actuators to cause the actions identified by the Tactics Layer to be carried out, and provide the converted commands to the one or more vehicle actuators.

2. The vehicle of claim 1, wherein to construct the virtual environment the Awareness Layer is configured to transform raw sensor data from the one or more vehicle sensors and communication data from the communication system into a current state estimate of the virtual environment and the one or more virtual actors.

3. The vehicle of claim 2, wherein to predict the future states of the virtual environment and the one or more virtual actors, the Awareness Layer is configured to predict the future states of the virtual environment and the one or more virtual actors based on the current state estimate of the virtual environment and the one or more virtual actors and a likely course of action for the one or more virtual actors.

4. The vehicle of claim 1, wherein the Awareness Layer is further configured to parse the communication data and provide relevant data or instructions from the communication data to one or more of the Strategy Layer, the Tactics Layer, and the Execution Layer.

5. The vehicle of claim 1, wherein the Strategy Layer is further configured to decide when to transition to a next task.

6. The vehicle of claim 1, wherein the Awareness Layer orients, the Strategy Layer and Tactics Layer decide, and the Execution Layer acts and observes.

7. The vehicle of claim 1, wherein the Execution Layer is further configured to provide open standard APIs for use in interfacing with the autonomous agent.

8. The vehicle of claim 1, wherein the Execution Layer is further configured to control the one or more vehicle actuators based on the set of commands made by the Tactics Layer and provide raw sensor data from the one or more vehicle sensors and the communication data from the communication system to the Awareness Layer.

9. The vehicle of claim 1, wherein the vehicle comprises an aerial vehicle or space vehicle.

10. The vehicle of claim 1, wherein the vehicle comprises a land vehicle or watercraft.

11. The vehicle of claim 1, wherein the vehicle comprises a fixed-in-place vehicle.

12. A method in a vehicle, comprising:
providing a controller organized with an Awareness Layer, a Strategy Layer, a Tactics Layer, and an Execution Layer;
receiving, by the Execution Layer, input from a communication system in the vehicle that is configured to receive communication data from an entity external to the vehicle regarding mission objectives or commander intent;
receiving, by the Execution Layer, input from one or more vehicle sensors configured to provide state information regarding the vehicle;
constructing, via the Awareness Layer, a virtual environment that includes one or more virtual actors that are capable of making decisions and predicting, via the Awareness Layer, future states of the virtual environment and the one or more virtual actors;
choosing, via the Strategy Layer, an operating scheme comprising one or more tasks for the vehicle to execute based on mission objectives or a commander intent;
executing one or more behavioral algorithms by the Tactics Layer;
identifying actions for implementing the operating scheme based on executing the one or more behavioral algorithms by the Tactics Layer;
expressing, by the Tactics Layer, the actions as a set of commands for the Execution Layer;
converting, by the Execution Layer, the commands from the Tactics Layer to commands for vehicle actuators to cause the actions identified by the Tactics Layer to be carried out; and
providing, by the Execution Layer, the converted commands to one or more vehicle actuators.

13. The method of claim 12, wherein constructing the virtual environment comprises transforming raw sensor data from the one or more vehicle sensors and communication data from the communication system into a current state estimate of the virtual environment and the one or more virtual actors.

14. The method of claim 13, wherein predicting the future states of the virtual environment and the one or more virtual actors comprises predicting the future states of the virtual environment and the one or more virtual actors based on the current state estimate of the virtual environment and the one or more virtual actors and a likely course of action for the one or more virtual actors.

15. The method of claim 12, further comprising parsing, via the Awareness Layer, the communication data and providing relevant data or instructions from the communication data to one or more of the Strategy Layer, the Tactics Layer, and the Execution Layer.

16. The method of claim 12, further comprising deciding when to transition to a next task via the Strategy Layer.

17. The method of claim 12, wherein the Awareness Layer orients, the Strategy Layer and the Tactics Layer decide, and the Execution Layer acts and observes.

18. A swarm system comprising:
a plurality of vehicles, wherein each of the plurality of vehicles comprises an autonomous agent for directing vehicle behavior, the autonomous agent comprising a controller organized with an Awareness Layer, a Strategy Layer, a Tactics Layer, and an Execution Layer;
wherein the Awareness Layer is configured to:
construct a virtual environment representative of a real environment that includes one or more virtual actors that represent one or more real entities in the real environment that are capable of making decisions; and
predict future states of the virtual environment and the one or more virtual actors;
wherein the Strategy Layer is configured to choose an operating scheme comprising one or more tasks for the vehicle to execute based on mission objectives or commander intent;
wherein the Tactics Layer is configured to:
execute one or more behavioral algorithms to identify actions for implementing the operating scheme; and
express the actions as a set of commands for to the Execution Layer;
wherein the Execution Layer is configured to receive input from a communication in the vehicle system and one or more vehicle sensors, convert the commands from the Tactics Layer to commands for vehicle actuators to cause the actions identified by the Tactics Layer to be carried out, and provide the converted commands to one or more vehicle actuators;
wherein the autonomous agent in a vehicle in the swarm system is configured to share one or more of operating scheme, identified actions, virtual environment data, virtual actor data, or raw sensor data with another autonomous agent in a vehicle in the swarm system; and
wherein the autonomous agent in each vehicle in the swarm system is configured to make decisions using its Strategy Layer and the Tactics Layer independently of decisions made by the autonomous agent in other vehicles in the swarm system.

19. The swarm system of claim 18, wherein the Awareness Layers in the plurality of vehicles are configured to be synchronized or distributed across the autonomous agents in multiple vehicles.

20. The swarm system of claim 18, wherein an autonomous agent in a leader vehicle is configured with the Strategy Layers and Tactics Layers of other autonomous agents in the swarm system to calculate schemes and commands and send instructions to teammates after the autonomous agent in the leader vehicle has decided a best course of action.
